(19) United States
(12) Patent Application Publication
(10) Pub. No.: US 2006/0043566 A1
(43) Pub. Date: Mar. 2, 2006

(54) Electronic component package

(75) Inventor: Masahiko Nakanishi, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 11/094,165

(22) Filed: Mar. 31, 2005

(30) Foreign Application Priority Data
Aug. 25, 2004 (JP) 2004-245850

(51) Int. Cl. H01L 23/495

(52) U.S. Cl. 257/690

(57) ABSTRACT

An electronic component package includes an electronic component substrate disposed on a dice pad, a plurality of leads disposed around the dice pad, wires connecting the leads and signal pads of the electronic component substrate, and a molding resin for sealing the dice pad, the electronic component substrate, and the wires such that the bottom surfaces and one end surfaces of the leads are exposed, wherein the one end surfaces of the leads do not protrude out of the molding resin, and recessions that open at the one end surfaces are formed in the bottom surfaces of the leads.

### BACKGROUND OF THE INVENTION

1. Field of the Invention

The present invention relates to an electronic component package and, more particularly, to a type of electronic component package represented by a quad flat non-leaded package (QFN) in which no electrical connection leads jut out of side surfaces of a package.

2. Background Art

FIG. 12 is a partly cutaway perspective view showing a schematic construction of a conventional QFN package.

As shown in the figure, a package 6 is composed of an electronic component substrate 2, such as a semiconductor chip, disposed and secured onto a dice pad 1, a plurality of leads 3 arranged side by side around the dice pad 1, wires 4 for connecting signal pads of the semiconductor chip 2 and predetermined ones of the leads 3, and a molding resin 5 that seals the dice pad 1, the semiconductor chip 2, and the wires 4 such that bottom surfaces 3A and one end surfaces 3B of the leads 3 are exposed.

A fabricating method for the package 6 will be briefly explained. A plurality of the packages 6 is formed on a mold metal plate 7, which is called a “matrix frame”, shown in FIG. 13, and a region constituting the leads 3 is formed around each of the packages 6. Further, the dice pad 1 and the semiconductor chip 2 shown in FIG. 12 are disposed at the center of each of the packages 6, and then a film is attached to the bottom surface of the matrix frame 7 to prevent a molding resin from flowing under the bottom surface of the leads 3. Thereafter, the matrix frame 7 is placed in a mold for resin molding to seal the top surface of an entire region with a molding resin 5 by a well-known method.

In this state, the packages 6 that are adjacent to each other are connected by the leads 3, and all the packages are sealed with the molding resin 5. Therefore, a dicing blade (not shown) for cutting, for example, is pressed against the top surface of the molding resin 5, and then moved in the vertical direction and the horizontal direction along the boundaries of the adjacent packages 6. This separates the plurality of sealed packages into individual packages 6 shown in FIG. 12 (refer to, for example, Japanese Unexamined Patent Application Publication No. 2001-77279, paragraphs 0031 to 0048, FIG. 1 to FIG. 8).

The matrix frame 7 of the conventional electronic component package constructed as described above frequently uses a metal made primarily of copper, which features low electrical resistance and outstanding heat conduction. This material is used also for the leads 3 around the packages; however, using it as it is would not be compatible with solder because of an oxide film formed on its surface, which Is inconvenient for the leads 3. For this reason, the entire surface of the matrix frame 7 is provided with, for example, palladium plating.

Meanwhile, each of the packages 6 is subjected to cutting by the dicing blade or the like, so that the external end surfaces 3B exposed on the peripheral face of the package are the cut surfaces produced by the dicing blade or the like, as illustrated by FIG. 14, which is an enlarged view of the lead 3. Sine a core material of the matrix frame 7 is exposed, when the bottom surface 3A of the lead 3 is connected with a solder 9 to a connection (not shown) of a circuit board 8, as shown in FIG. 15, even if the bottom surface 3A of the lead 3 is firmly connected to the connection of the circuit board 8, the solder 9 does not crawl up the end surface 3B, because the external end surface 3B of the lead 3 does not easily conform with the solder 9. As a result, no solder fillets are formed onto the end surface 3B, posing a problem in that it is difficult to check whether soldering to the circuit board 8 has been successfully accomplished when observed from above the package 6.

There has been another problem in that the leads 3 are strongly pressed downward from above by a dicing blade or the like to separate the packages from each other in the manufacturing process, so that peeling may take place between the molding resin 5 and a top surface 3C of a lead. As a result, water or the like may enter through a peeled portion, leading to deteriorated performance of the electronic component.

To reduce the likelihood of the aforesaid problem, according to the one disclosed in Japanese Unexamined Patent Application Publication No. 2001-77279, the portions of the leads 3 which are cut by a dicing blade are formed to be thin. However, the thin portions decrease the strength of the leads 3, posing a problem in that the leads 3 tend to be deformed when they are cut, easily causing peeling to take place between the molding resin 5 and the leads 3.

### SUMMARY OF THE INVENTION

The present invention has been made with a view toward solving the problems described above, and it is an object of the invention to provide an electronic component package that allows a solder fillet to be easily formed at an end surface of a lead so as to permit easy observation of the solder fillet from above the package, thereby making it possible to easily check whether successful connection to a circuit board has been accomplished by soldering, and that is resistant to peeling between a molding resin and a lead.

According to one aspect of the present invention, an electronic component package includes an electronic component substrate disposed on a dice pad, a plurality of leads disposed around the dice pad, wires connecting the leads and signal pads of the electronic component substrate, and a molding resin for sealing the dice pad, the electronic component substrate, and the wires such that the bottom surfaces and one end surfaces of the leads are exposed, wherein the one end surfaces of the leads do not protrude out of the molding resin, and recessions that open at the one end surfaces are formed in the bottom surfaces of the leads.

Since the electronic component package in accordance with the present invention is constructed as described above, a solder fillet can be easily formed at an end surface of a lead, thus making it possible to easily check whether the package and a board have been successfully connected with solder by checking the solder fillet from above the package.

Moreover, a recession in a top surface of a lead is filled with a molding resin to increase the area wherein the molding resin is in contact with the lead so as to restrain the occurrence of peeling between the molding resin and the lead.

In addition, the recession is provided in the bottom surface or the top surface of the lead so as to reduce the area of an external end surface of the lead without changing the height of the lead. Therefore, the stress applied to each lead when the package is subjected to the cutting process by a dicing blade or the like is reduced, further reducing the chance of peeling to take place between the molding resin and the lead.

Other and further objects, features and advantages of the invention will appear more fully from the following description.

### BRIEF DESCRIPTION OF THE DRAWINGS

FIG. 1 is a perspective view showing a schematic configuration of a first embodiment in accordance with the present invention;

FIG. 2 is an enlarged view showing the construction of a lead of the first embodiment;

FIG. 3 is a schematic diagram of a package observed from an external end surface side of the leads in the first embodiment;

FIG. 4 is a schematic diagram showing a sectional construction of a lead of the first embodiment taken along line A-A in FIG. 3, and surface treatment;

FIG. 5 is a schematic sectional view showing the package mounted on a circuit board in the first embodiment;

FIG. 6 is an enlarged view showing the construction of a lead of a second embodiment in accordance with the present invention;

FIG. 7 is a schematic diagram of the a package observed from an external end surface side of the leads in the second embodiment;

FIG. 8 is a schematic sectional view showing the package mounted on a circuit board in the second embodiment;

FIG. 9 is an enlarged view showing the construction of a lead of a third embodiment;

FIG. 10 is a schematic diagram showing a package observed from an external end surface side of the leads in the third embodiment;

FIG. 11 is a schematic sectional view showing the package mounted on a circuit board in the third embodiment;

FIG. 12 is a perspective view showing the schematic construction of a conventional QFN package;

FIG. 13 is a perspective view showing the schematic construction of a matrix frame;

FIG. 14 is an enlarged view showing the construction of a conventional lead; and

FIG. 15 is a schematic diagram showing a sectional construction of the conventional lead.

### DETAILED DESCRIPTION OF THE PREFERRED EMBODIMENTS

First Embodiment

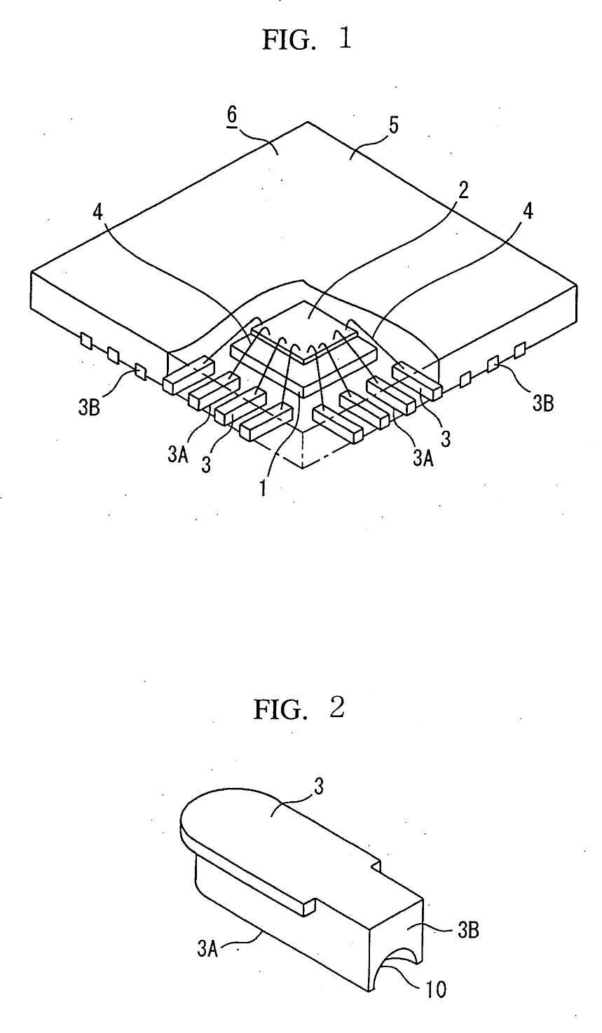

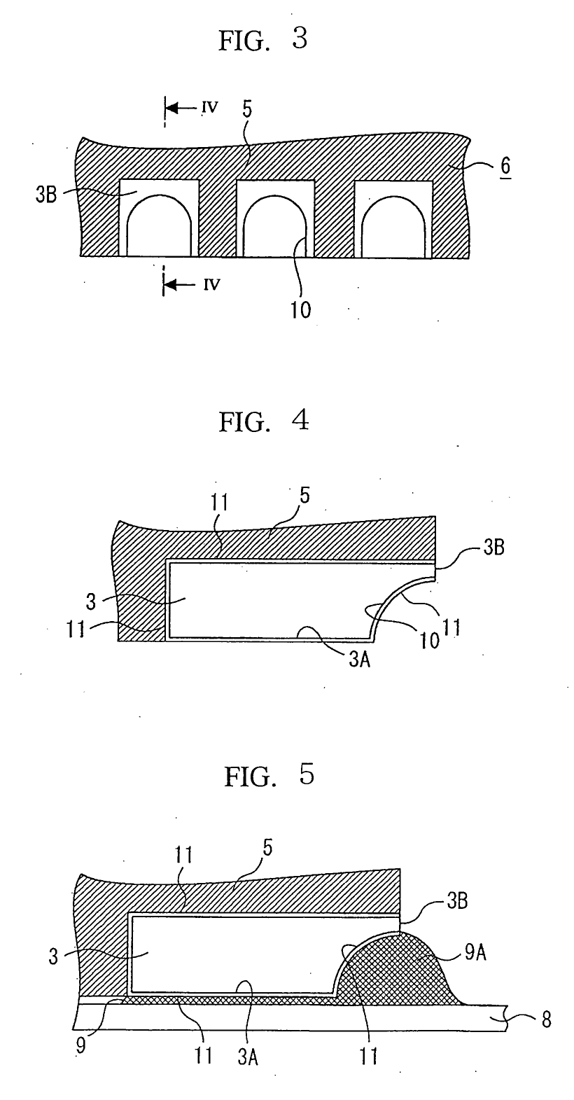

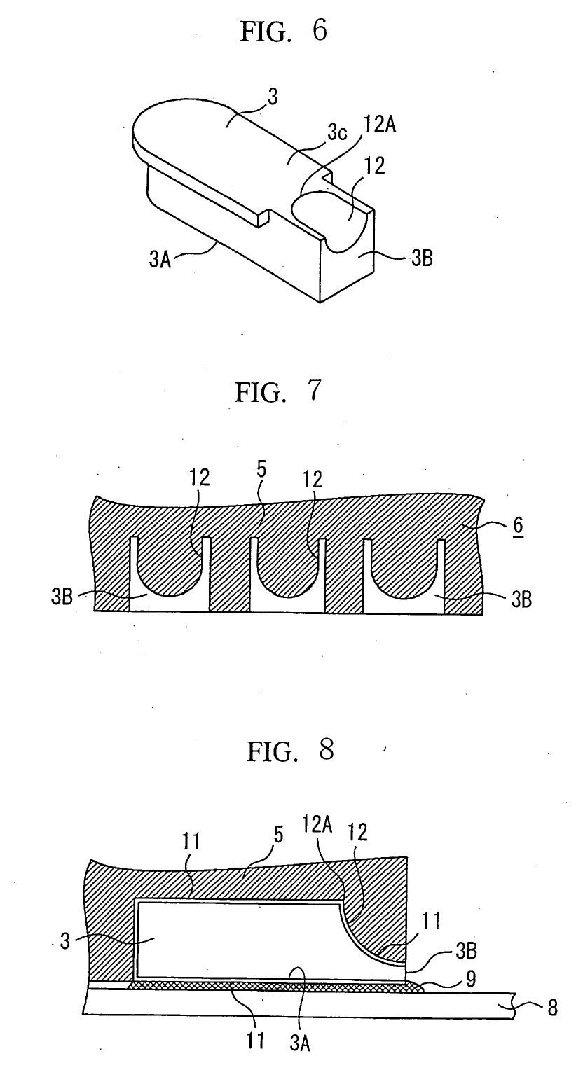

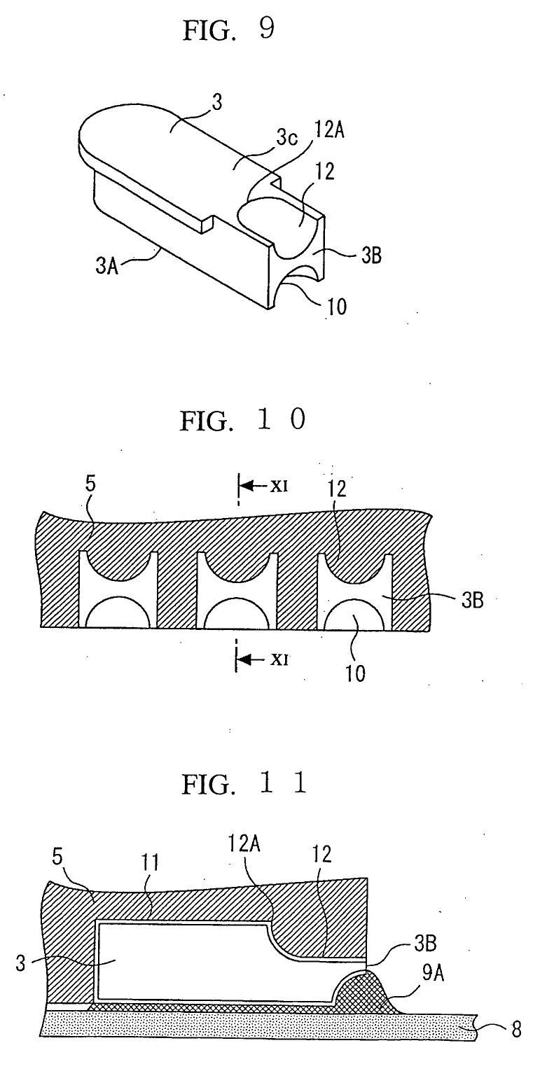

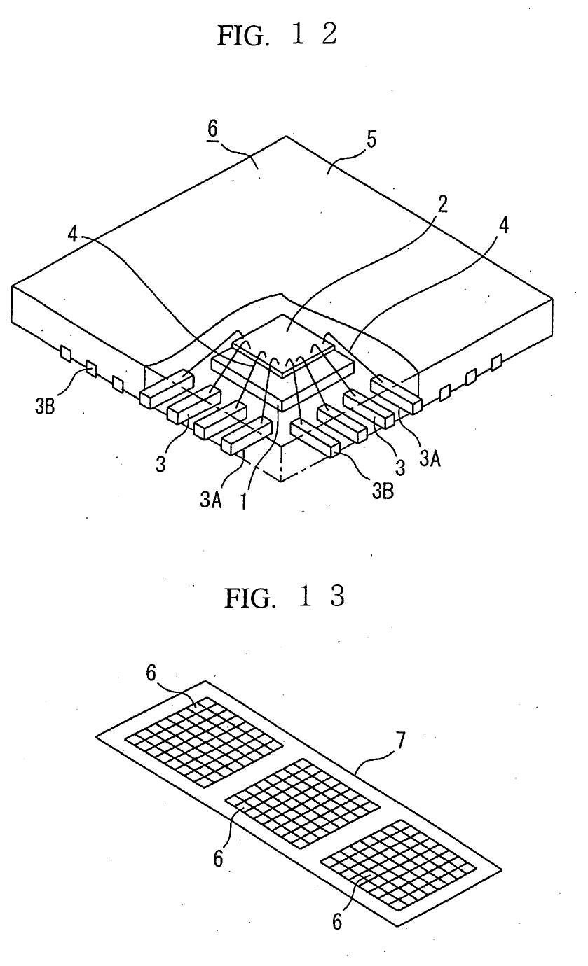

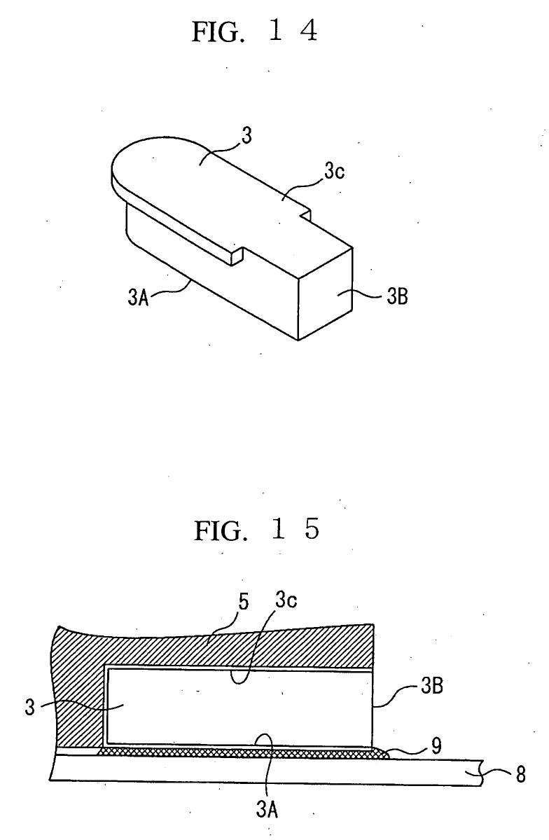

A first embodiment of the present invention will be described with reference to the accompanying drawings. FIG. 1 is a partly cutaway perspective view showing a schematic construction of the first embodiment. FIG. 2 is an enlarged view showing a construction of a lead of the first embodiment. FIG. 3 is a schematic diagram of a package observed from an external end surface side of leads.

As shown in the figures, a package 6 is constructed of an electronic component substrate 2, such as a semiconductor chip, disposed and secured on a dice pad 1, a plurality of leads 3 that are formed of a frame core material and arranged side by side around the dice pad 1, as in the prior art described above, wires 4 connecting signal pads of the semiconductor chip 2 and predetermined leads 3, and a molding resin 5 that seals the dice pad 1, the semiconductor chip 2, and the wires 4 such that bottom surfaces 3A and one end surfaces 3B of the leads 3 are exposed.

As shown in FIG. 2, which is the enlarged view of the lead 3, a recession 10 that opens at the end surface 3B is formed in a portion of the bottom surface 3A of the lead 3, the portion being near the end surface 3B. The recession 10 is formed beforehand by, for example, corroding the portion of a matrix frame 7 itself wherein leads will be formed. Hence, as described above, the inner surface of the recession 10 is provided with a palladium plating layer 11, as shown in FIG. 4, when the entire matrix frame 7 is plated with palladium.

Accordingly, when the package 6 is mounted on a circuit board 8 through the intermediary of the leads 3, as shown in FIG. 5, the palladium plating layer 11 allows the bottom surfaces 3A of the leads 3 to be secured sufficiently firmly to a connection of the circuit board 8 by a solder 9 because the palladium plating layer 11 is compatible with solder. Furthermore, a solder fillet 9A bulges until it reaches the inner surface of the recession 10 and also juts out beyond the external end surface 3B, as illustrated, thus allowing the solder fillet 9A to be easily observed from above the package. This in turn makes it possible to check that the lead 3 has been firmly secured to the circuit board 8 by checking for the solder fillet 9A.

Second Embodiment

A second embodiment according to the present invention will now be explained in conjunction with the accompanying drawings. The construction of a package 6 is identical to that shown in FIG. 1 except for leads; therefore, the description will be omitted with the aid of FIG. 1.

FIG. 6 is an enlarged view showing the construction of a lead of the second embodiment. FIG. 7 is a schematic diagram showing the package 6 observed from an external end surface 3B of a lead 3. FIG. 8 is a schematic diagram showing the package 6 mounted on a circuit board 8.

As shown in the figures, a recession 12 that opens at the end surface 3B is formed in a portion of a top surface 3C of the lead 3, the portion being near the end surface 3B. The recession 12 is formed beforehand by, for example, corroding the portion of a matrix frame 7 itself wherein leads will be formed. Hence, the inner surface of the recession 12 is provided with a palladium plating layer 11, as in the case of the recession 10 in the first embodiment.

The place where the recession 12 is formed is not limited to the portion opening to the end surface 3B. The recession 12 may alternatively be formed in a portion located on an inner side of the top surface 3C of the lead.

According to the second embodiment, since the recession 12 is formed in the top surface 3C of the lead 3, the recession 12 is also filled with the molding resin 5 when the entire package is sealed with a molding resin 5, as illustrated in FIGS. 7 and 8. Furthermore, the thickness of the lead 3 remains unchanged after the recession 12 is provided, so that the bending strength of the lead 3 remains substantially unchanged. Hence, when the package is subjected to cutting by a dicing blade, a stress produced by a force applied to the lead 3 downward from above the package 6 is dispersed over an increased area of contact between the molding resin 5 and the lead 3. This arrangement restrains peeling between the molding resin 5 and the lead 3.

Even if peeling should take place in the interface between the recession 12 of the lead 3 and the molding resin 5, a curved portion 12A extending inward from the outer side interrupts the peeling in the middle of developing inward from the outer side of the package. This makes it possible to prevent the peeling from reaching inside the package.

Third Embodiment

A description will now be given of a third embodiment that combines the first and the second embodiments with reference to the accompanying drawings. The construction of a package 6 is identical to that shown in FIG. 1 except for leads; therefore, the description will be omitted with the aid of FIG. 1. FIG. 9 is an enlarged view showing the construction of a lead of the third embodiment. FIG. 10 is a schematic diagram showing the package 6 observed from an external end surface 3B of a lead 3. FIG. 11 is a schematic diagram showing the package 6 mounted on a circuit board 8, the package 6 including the leads that have a sectional construction illustrated in FIG. 11, wherein the section has been taken along line B-B shown in FIG. 10.

As shown in the figures, a recession 10 and a recession 12 that open at an end surface 3B are formed in a portion of a bottom surface 3A and a portion of a top surface 3C of the lead 3, respectively, the portions being near the end surface 3B. The details of these recessions are the same as those in the first and the second embodiments, so that the description will not be repeated.

As shown in FIG. 11, according to the third embodiment, when the package 6 is mounted on the circuit board 8 through the intermediary of the leads 3, a solder fillet 9A bulges until it reaches the inner surface of the recession 10 and also juts out beyond the external end surface 3B, as illustrated, thus allowing the solder fillet 9A to be easily observed from above the package. This in turn makes it possible to check that the lead 3 has been firmly secured to the circuit board 8 by checking for the solder fillet 9A. In addition, the recession 12 filled with the molding resin 5 disperses a stress applied to the surface of contact between the molding resin 5 and the leads 3, thus restraining peeling from taking place between the molding resin 5 and the leads 3. Even if peeling should occur on the interface between the recessions 12 of the leads 3 and the molding resin 5, the curved portions 12A block the peeling from reaching inside the package.

In the embodiments described above, the semiconductor chips have been used as examples of the electronic component substrate 2; however, the present invention is not limited thereto. Obviously, the present invention provides the same advantages when it is applied to an electronic component based on ceramic or diamond in place of a semiconductor chip.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2004-245850, filed on Aug. 25, 2004 including specification, claims, drawings and summary, on which the Convention priority of the present application is based, are incorporated herein by reference in its entirety.

1. An electronic component package comprising:
an electronic component substrate disposed on a die pad;
a plurality of leads disposed around the die pad;
wires connecting the leads and signal pads of the electronic component substrate; and
a molding resin sealing the die pad, the electronic component substrate, and the wires such that bottom surfaces and first end surfaces of the leads are exposed, wherein the first end surfaces of the leads do not protrude from the molding resin, and the first end surfaces include recesses in the bottom surfaces of the leads.

2. The electronic component package according to claim 1, wherein inner surfaces of the recesses include a surface treatment of a material different from the material of the leads.

3. The electronic component package according to claim 1, wherein the first end surfaces of the leads are exposed from the molding resin to expose the material of the leads.

4. The electronic component package according to claim 2, wherein the first end surfaces of the leads are exposed from the molding resin to expose the material of the leads.

5. An electronic component package comprising:
an electronic component substrate disposed on a die pad;
a plurality of leads disposed around the die pad;
wires connecting the leads and signal pads of the electronic component substrate; and
a molding resin sealing the die pad, the electronic component substrate, and the wires such that bottom surfaces and first end surfaces of the leads are exposed, wherein the first end surfaces of the leads do not protrude from the molding resin, and the first end surfaces include recesses in top surfaces of the leads, the recesses being filled with the molding resin.

6. The electronic component package according to claim 1, wherein the recesses that open at the first end surfaces are also in top surfaces of the leads, and the recesses in the top surfaces are filled with the molding resin.

7. The electronic component package according to claim 3, wherein the recesses that open at the first end surfaces are also in top surfaces of the leads, and the recesses in the top surfaces are filled with the molding resin.

8. The electronic component package according to claim 4, wherein the recesses that open at the first end surfaces are also in top surfaces of the leads, and the recesses in the top surfaces are filled with the molding resin.

9. The electronic component package according to claim 1, wherein
the recesses that open at the first end surfaces are also in top surfaces of the leads,
inner surfaces of the recesses in the top surfaces and the bottom surfaces are surface treated with a material different from the material of the leads, and
the recesses in the top surfaces are filled with the molding resin.
